(19) United States
(12) Patent Application Publication
(10) Pub. No.: US 2024/0118870 A1
(43) Pub. Date: Apr. 11, 2024

(54) Digital Signal Processing Circuitry with Multiple Precisions and Dataflows

(71) Applicant: Intel Corporation, Santa Clara, CA (US)

(72) Inventor: Martin Langhammer, Alderbury (GB)

(21) Appl. No.: 18/373,878

(22) Filed: Sep. 27, 2023

Related U.S. Application Data
(60) Provisional application No. 63/414,189, filed on Oct. 7, 2022.

(51) Int. Cl. G06F 7/544; G06F 30/34

(52) U.S. Cl. CPC G06F 7/5443; G06F 30/34

(57) ABSTRACT

Integrated circuit devices, methods, and circuitry for a digital signal processing (DSP) block that can selectively perform higher-precision DSP multiplication operations or lower-precision AI tensor multiplication operations. Flexible digital signal processing circuitry may include hardened multipliers, hardened summation circuitry, and an intermediate multiplexer network. The intermediate multiplexer network may be configurable to, in a first configuration, route data between the plurality of hardened multipliers and the hardened summation circuitry to perform a plurality of lower-precision multiplication operations. In a second configuration, the intermediate multiplexer network may route the data between the plurality of hardened multipliers and the hardened summation circuitry to perform at least one higher-precision multiplication operation.

### BACKGROUND

This application claims priority to U.S. Provisional Application No. 63/414,189, entitled “DIGITAL SIGNAL PROCESSING BLOCK WITH MULTIPLE PRECISIONS AND DATAFLOWS,” filed Oct. 7, 2022, the disclosure of which is incorporated by reference in its entirety for all purposes.

### BACKGROUND

The present disclosure relates generally to integrated circuit (IC) devices such as programmable logic devices (PLDs). More particularly, the present disclosure relates to digital signal processing circuitry that may support multiple precisions and dataflows.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Many digital signal processing (DSP) Blocks are either regular DSP blocks (e.g., INT18 based) or artificial intelligence (AI) Tensor Blocks (e.g., large numbers of small multipliers). Yet these two approaches do not use compatible arithmetic architectures, making it difficult to perform both digital signal processing and AI operations using the same integrated circuit device.

### BRIEF DESCRIPTION OF THE DRAWINGS

Various aspects of this disclosure may be better understood upon reading the following detailed description and upon reference to the drawings in which:

FIG. 1 illustrates a block diagram of a system that may implement arithmetic operations using a digital signal processing (DSP) block;

FIG. 2 illustrates an example of the integrated circuit device as a programmable logic device, such as a field-programmable gate array (FPGA);

FIG. 3 is a block diagram of an FPGA digital signal processing (DSP) block;

FIG. 4 is a block diagram of an FPGA artificial intelligence (AI) tensor block;

FIG. 5 is a block diagram of logical components of a DSP block with DSP and AI tensor functionality;

FIG. 6 is a block diagram of a detailed view of the DSP block with DSP and AI tensor dataflow of FIG. 5;

FIG. 7 is a block diagram of a physical implementation of one column of the DSP block with DSP and AI tensor functionality of FIG. 6;

FIG. 8 is a block diagram of a physical implementation of another column of the DSP block with DSP and AI tensor functionality of FIG. 6;

FIG. 9 is a block diagram illustrating an implementation of the tensor structure of the DSP block with AI tensor functionality;

FIG. 10 is a block diagram of a multiplexer pattern used to obtain a variety of different precisions and dataflows from the DSP block with DSP and AI tensor functionality; and

FIG. 11 is a block diagram of a data processing system incorporating the DSP block with DSP and AI tensor functionality.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

The present systems and techniques relate to embodiments for a type of arithmetic construct, referred to herein as a digital signal processing (DSP) block, that composes larger multipliers from a set of smaller multipliers, supporting both tensor operations and larger DSP operations, including floating point. The DSP block of this disclosure is backwards compatible to one or more types of FPGA devices (e.g., Intel® Agilex® FPGA and SoC FPGA family by Intel Corporation) and also contain the equivalent of approximately two thirds of an AI tensor block found in another type of FPGA device (e.g., an NX FPGA by Intel®). The DSP block of this disclosure supports both regular and artificial intelligence (AI) digital signal processing, and at a higher density. For example, complex multipliers (e.g., 4 real multipliers) can now be directly supported in a single DSP block.

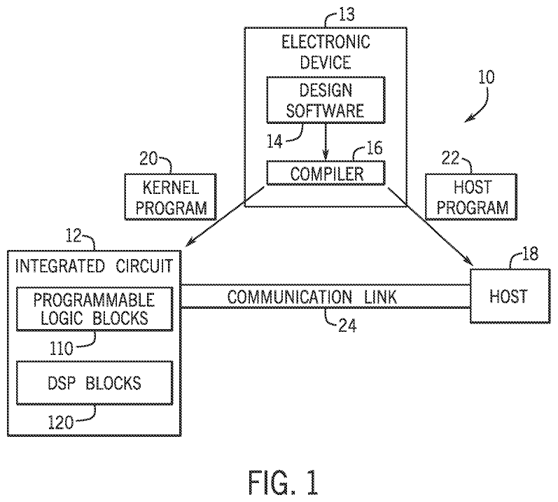

With the foregoing in mind, FIG. 1 illustrates a block diagram of a system 10 that may be used in configuring an integrated circuit device 12 with such a DSP block. A designer may desire to implement testbench functionality on the integrated circuit device 12 (e.g., a programmable logic device such as a field-programmable gate array (FPGA) or an application-specific integrated circuit (ASIC) that includes programmable logic circuitry). The integrated circuit device 12 may include a single integrated circuit, multiple integrated circuits in a package (e.g., a multi-chip module (MCM), a system-in-package (SiP)), or multiple integrated circuits in multiple packages communicating remotely (e.g., via wires or traces). In some cases, the designer may specify a high-level program to be implemented, such as an OPENCL® program that may enable the designer to more efficiently and easily provide programming instructions to configure a set of programmable logic cells for the integrated circuit device 12 without specific knowledge of low-level hardware description languages (e.g., Verilog, very high speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

In a configuration mode of the integrated circuit device 12, a designer may use an electronic device 13 (e.g., a computer) to implement high-level designs (e.g., a system user design) using design software 14, such as a version of INTEL® QUARTUS® by INTEL CORPORATION. The electronic device 13 may use the design software 14 and a compiler 16 to convert the high-level program into a lower-level description (e.g., a configuration program, a bitstream). The compiler 16 may provide machine-readable instructions representative of the high-level program to a host 18 and the integrated circuit device 12. The host 18 may receive a host program 22 that may be implemented by the kernel programs 20. To implement the host program 22, the host 18 may communicate instructions from the host program 22 to the integrated circuit device 12 via a communications link 24 that may be, for example, direct memory access (DMA) communications or peripheral component interconnect express (PCIe) communications. In some embodiments, the kernel programs 20 and the host 18 may enable configuration of circuits including programmable logic blocks 110 and digital signal processing (DSP) blocks 120 on the integrated circuit device 12. The programmable logic blocks 110 may include circuitry and/or other logic elements and may be configurable to implement a variety of functions in combination with digital signal processing (DSP) blocks 120. The DSP blocks 120 may include circuitry to implement, for example, operations to perform matrix-matrix or matrix-vector multiplication for AI or non-AI data processing. The integrated circuit device 12 may include many (e.g., hundreds or thousands) of the DSP blocks 120. Additionally, DSP blocks 120 may be communicatively coupled to another such that data outputted from one DSP block 120 may be provided to other DSP blocks 120. A DSP block 120 may include hardened circuitry that is purpose-built for performing arithmetic operations. The hardened arithmetic circuitry of the DSP blocks 120 may be contrasted with arithmetic circuitry that may be constructed in soft logic in the programmable logic circuitry (e.g., the programmable logic blocks 110). While circuitry for performing the same arithmetic operations may be programmed into the programmable logic circuitry (e.g., the programmable logic blocks 110), doing this may take up significantly more die area, may consume more power, and/or may consume more processing time.

The designer may use the design software 14 to generate and/or to specify a low-level program, such as the low-level hardware description languages described above. Further, in some embodiments, the system 10 may be implemented without a separate host program 22. Thus, embodiments described herein are intended to be illustrative and not limiting.

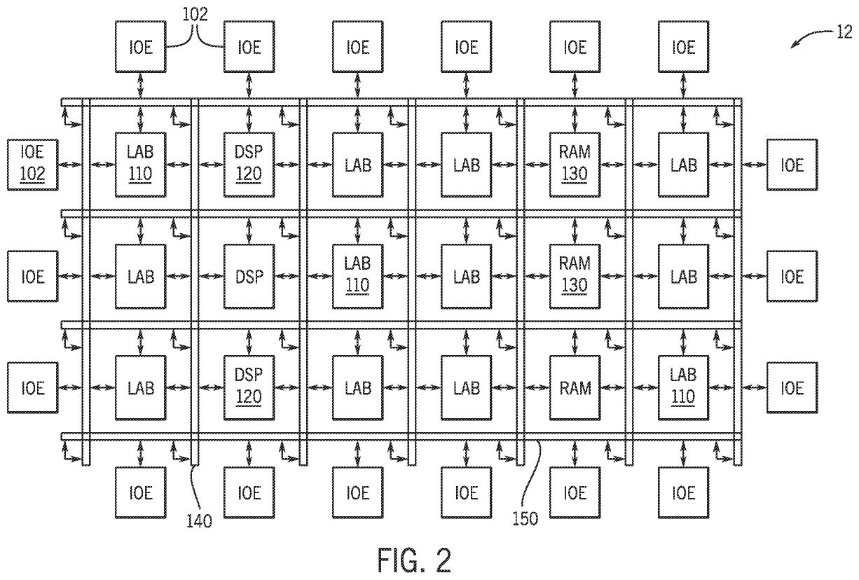

An illustrative embodiment of a programmable integrated circuit device 12 such as a programmable logic device (PLD) that may be configured to implement a circuit design is shown in FIG. 2. As shown in FIG. 2, the integrated circuit device 12 (e.g., a field-programmable gate array integrated circuit die) may include a two-dimensional array of functional blocks, including programmable logic blocks 110 (also referred to as logic array blocks (LAB s) or configurable logic blocks (CLBs)) and other functional blocks, such as random-access memory (RAM) blocks 130 and digital signal processing (DSP) blocks 120, for example. Functional blocks such as LAB s 110 may include smaller programmable regions (e.g., logic elements, configurable logic blocks, or adaptive logic modules) that receive input signals and perform custom functions on the input signals to produce output signals. LAB s 110 may also be grouped into larger programmable regions sometimes referred to as logic sectors that are individually managed and configured by corresponding logic sector managers. The grouping of the programmable logic resources on the integrated circuit device 12 into logic sectors, logic array blocks, logic elements, or adaptive logic modules is merely illustrative. In general, the integrated circuit device 12 may include functional logic blocks of any suitable size and type, which may be organized in accordance with any suitable logic resource hierarchy.

Programmable logic the integrated circuit device 12 may contain programmable memory elements. Memory elements may be loaded with configuration data (also called programming data or configuration bitstream) using input-output elements (IOEs) 102. Once loaded, the memory elements each provide a corresponding static control signal that controls the operation of an associated functional block (e.g., LAB s 110, DSP 120, RAM 130, or input-output elements 102).

In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory, configuration random-access memory (CRAM), or programmable memory elements. Programmable logic device (PLD) 100 may be configured to implement a custom circuit design. For example, the configuration RAM may be programmed such that LAB s 110, DSP 120, and RAM 130, programmable interconnect circuitry (i.e., vertical channels 140 and horizontal channels 150), and the input-output elements 102 form the circuit design implementation.

In addition, the programmable logic device may have input-output elements (IOEs) 102 for driving signals off of the integrated circuit device 12 and for receiving signals from other devices. Input-output elements 102 may include parallel input-output circuitry, serial data transceiver circuitry, differential receiver and transmitter circuitry, or other circuitry used to connect one integrated circuit to another integrated circuit.

The integrated circuit device 12 may also include programmable interconnect circuitry in the form of vertical routing channels 140 (i.e., interconnects formed along a vertical axis of the integrated circuit 100) and horizontal routing channels 150 (i.e., interconnects formed along a horizontal axis of the integrated circuit 100), each routing channel including at least one track to route at least one wire. If desired, the interconnect circuitry may include pipeline elements, and the contents stored in these pipeline elements may be accessed during operation. For example, a programming circuit may provide read and write access to a pipeline element.

Note that other routing topologies, besides the topology of the interconnect circuitry depicted in FIG. 1, are intended to be included within the scope of the present invention. For example, the routing topology may include wires that travel diagonally or that travel horizontally and vertically along different parts of their extent as well as wires that are perpendicular to the device plane in the case of three-dimensional integrated circuits, and the driver of a wire may be located at a different point than one end of a wire. The routing topology may include global wires that span substantially all of the integrated circuit device 12, fractional global wires such as wires that span part of the integrated circuit device 12, staggered wires of a particular length, smaller local wires, or any other suitable interconnection resource arrangement.

The integrated circuit device 12 may be programmed to perform a wide variety of operations. Indeed, many system designs that may be programmed into the integrated circuit device 12 may leverage the efficiency of performing arithmetic operations using the DSP blocks 120. Some system designs may employ the DSP blocks 120 to perform larger multiplication (e.g., on the order of a 27-bit integer (INT27) data type) while others, often used for tensor multiplications in artificial intelligence use cases, may employ the DSP blocks 120 to perform a very large number of multiplication operations of smaller precision (e.g., on the order of an 8-bit integer (INT8) data type). At least some of the DSP blocks 120 of the integrated circuit device 12 may be capable of being programmed to perform either type operation. Indeed, the DSP blocks 120 of this disclosure combine traditional FPGA embedded DSP Block precisions, numerics and use models, with AI Tensor Block precision and dataflows. The DSP blocks 120 may include a type of datapath construction that allows both types of processing to be fit into the same area that either DSP Block would have used according to prior techniques.

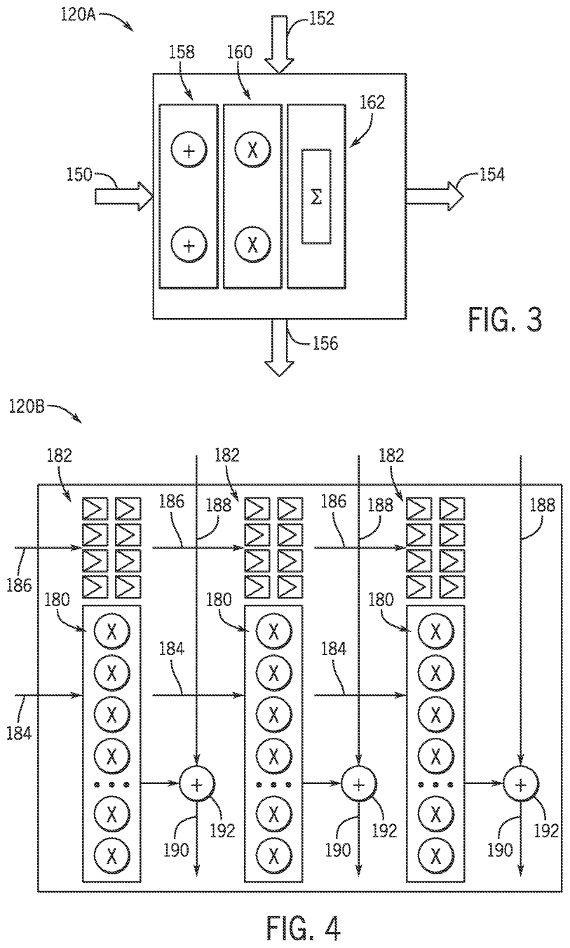

To illustrate the manner in which the DSP blocks 120 may operate as a type of DSP block found for performing larger multiplication operations (e.g., as in many digital signal processing use cases) as well as multiple smaller multiplications (e.g., as in many AI tensor multiplication cases), FIGS. 3 and 4 illustrate distinct blocks for digital signal processing and AI tensor use cases, respectively.

FIG. 3 shows a block diagram of an example of a DSP Block 120A with a distinct purpose of performing large multiplication operations (e.g., as often used in digital signal processing). A number of inputs and outputs (e.g., to global FPGA routing) are provided. These signals are limited as connections to global routing are very expensive. Inputs 150 and 152 may feed data of any suitable bit width into the DSP block 120A. By way of example, data of up to 108 bits may be fed into the input 150 while data of up to 72 bits may be fed into the input 152. Outputs 154 and 156 likewise may output data of any suitable width out of the DSP block 120A. In the illustrated example, the outputs 154 and 156 output data with a width of 72 bits. However, it should be appreciated that any other suitable bit widths may be used (e.g., 64, 96). Pre-adders 158 may be included, as well as several multipliers 160. The multipliers 160 may be of any suitable size (e.g., INT18 precision, INT16) and/or may be asymmetric (e.g., 18×19) and summation circuitry 162 may be used to sum or accumulate the results of the pre-adders 158 and/or multipliers 160. The pre-adders 158 can be used to efficiently implement symmetric finite impulse response (FIR) filters. Additional internal routing circuitry (not shown) can add the multipliers 160 together, chain the multipliers 160 together with adjacent DSP Blocks 120A or act as an accumulator via the summation circuitry 162, which may provide a summation of multiple internal results from the multipliers 160 or pre-adders 158. Additional internal routing circuitry (not shown) can combine the multipliers 160 to make larger multipliers (e.g., INT27) or even support floating point multiplication (e.g., IEEE754). The adder circuitry 158 or summation circuitry 162 can be fixed point or floating point.

FIG. 4 shows a block diagram of another form of DSP block 120B, illustrating a recent type of embedded FPGA resource known as an artificial intelligence (AI) Tensor Block. Instead of a small number of larger multipliers (e.g., INT18 multipliers) as in the DSP block 102A of FIG. 3, the DSP block 102B of FIG. 4 supports a very large number (e.g., 30) smaller multipliers 180 (e.g., as INT8) and includes banks of coefficient storage 182 so that data from one set can be preloaded while data from the other is processing. The number of inputs and outputs (IO) (e.g., bit width of data) into inputs 184, 186, and 188 and out of outputs 190 of the DSP block 120B of FIG. 4 may be unchanged from the inputs 150 and 152 of the DSP block 120A of FIG. 3. Indeed, the number of available inputs may be far less than the number that may be used to support all of the multipliers 180. For example, if there are 30 INT8 multipliers 180, this may take 30 multipliers*8 bits*2 values multiplied by each multiplier=480 inputs may be used, even though only 108 inputs may be available. In addition, using all 108 inputs for every block would stress the FPGA routing which may not be designed for 100% routing density for all inputs. As a result, only about ⅙th of the routing may be used to support the multipliers 180 (e.g., ⅙ of the total (480) involved is 80 bits, so about 75% of the number available). Virtual bandwidth expansion may be used, where one set of inputs is loaded for one of the inputs into the multipliers 180, and then streamed through a vector of the other input, to each of the multipliers 180, which may be arranged in groups of dot products. This dataflow lends itself well to AI applications, where matrix multiplications are common. Two banks of coefficient storage 182 are provided so that one set can be preloaded while the other is processing. Adders 192 may add the outputs of the multipliers 180 with the inputs 188 before being output on the outputs 190.

The two dataflows, precisions, and arithmetic datapath construction of the DSP blocks 120A and 120B have little in common using previously known architectures and datapath techniques. While separately incorporating both the DSP blocks 120A and 120B into the integrated circuit device 12 may be done to support system designs for either type of processing, this may be expensive and inefficient since the DSP blocks 120A and 120B tend to be found in distinct use cases. That is, use cases that employ the capabilities of the DSP block 120A tend not to employ the DSP block 120B, and vice versa. Thus, including both of the DSP blocks 120A and 120B may result in many of the blocks going unused.

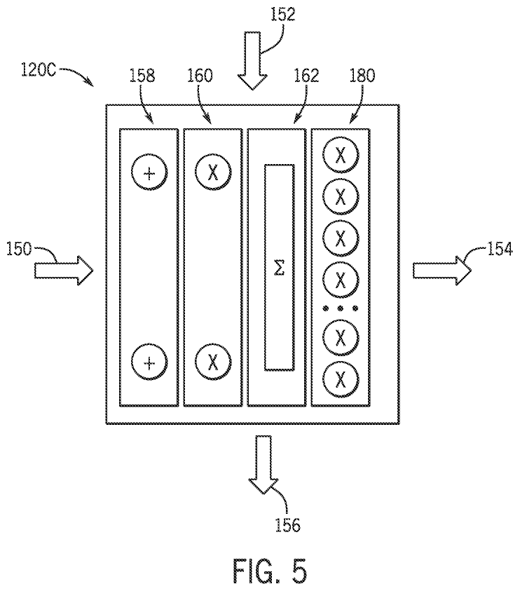

A new type of embedded FPGA arithmetic block shown as a DSP block 120C of FIG. 5 may combine various features of the DSP blocks 120A and 120B to enable the DSP block 120C to able to support either or both digital signal processing (DSP) use cases involving large multiply operations and AI operations involving numerous smaller multiply operations. Moreover, the DSP block 120C may take up substantially the same amount of die area as the DSP block 120A or the DSP block 120B. The DSP block 120C may support all of the use cases of the DSP block 120A (e.g., may be fully backwards compatible with system designs incorporating the DSP block 120A) and may support a large portion of system designs incorporating the DSP block 120B (e.g., may be fully backwards compatible with many AI Tensor system designs incorporating the DSP block 120B) all while taking up the same amount of die area.

FIG. 5 is a schematic diagram showing how more efficient arithmetic design techniques may be used to support both styles of processing (e.g., digital signal processing operations, AI tensor operations). The DSP block 120C includes inputs 150 and 152 and outputs 154 and 156, which may support any suitable data width. Indeed, the DSP block 120C may have the same data width as the DSP blocks 120A and 120B. In one particular example, data of up to 108 bits may be fed into the input 150 while data of up to 72 bits may be fed into the input 152. Outputs 154 and 156 likewise may output data of any suitable width out of the DSP block 120C. In the illustrated example, the outputs 154 and 156 output data with a width of 72 bits. However, it should be appreciated that any suitable bit widths may be used (e.g., 64, 96).

The DSP block 120C of FIG. 5 retains the pre-adder 158, large multiplier 160, summation circuitry 162 capabilities of the DSP block 120A, and gains the capability of one column of the AI Tensor capability of the multipliers 180 of the DSP block 120B. The regular functionality has been redesigned with this new method so that it can support both regular DSP and a tensor (a dot product of low precision arithmetic). This is accomplished by providing datapath routing so that the tensor multipliers 180 do not only support a dot product but can also have the multipliers 180 combined to create larger multipliers. In one case, the sum of two multipliers (e.g., INT16 multipliers) can be implemented, which, when combined with the two multipliers 160 of the regular DSP functionality, can implement a complex multiplier.

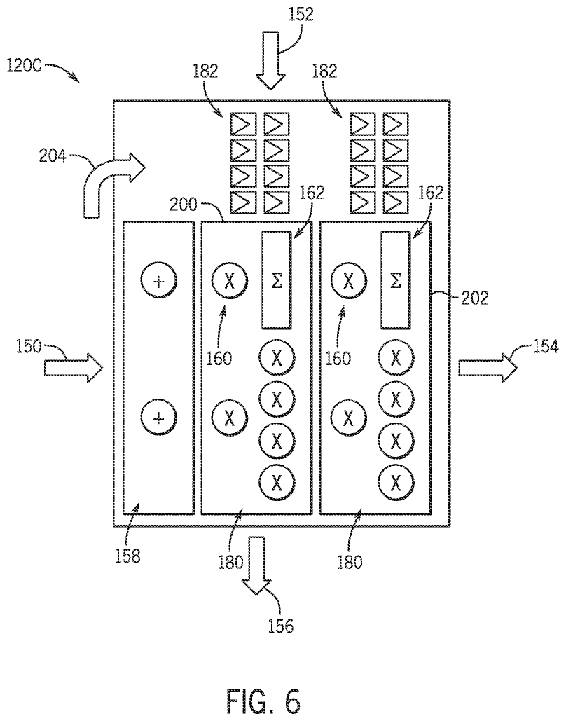

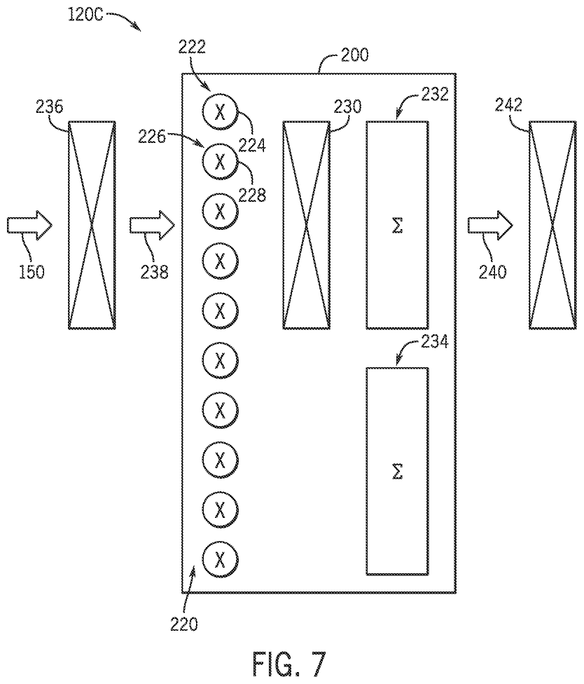

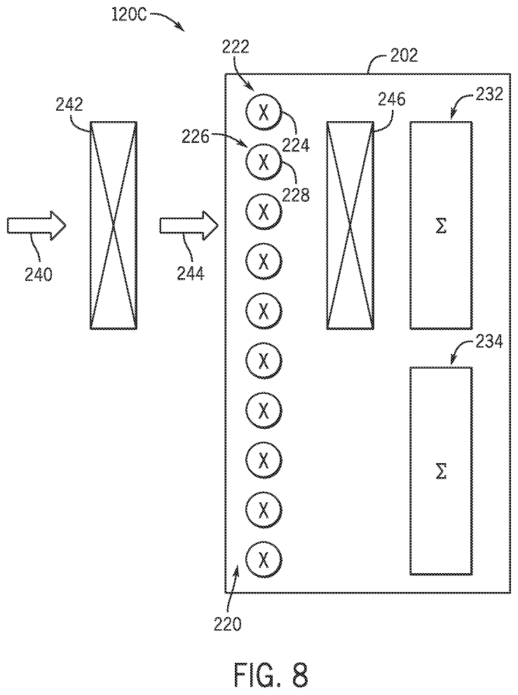

FIG. 6 shows a more detailed functional schematic view of the DSP block 120C of FIG. 5. Here, coefficient storage registers 182 can be seen, along with a functional logical representation of arithmetic columns 200 and 202 that may represent collections of the multipliers 160, summation circuitry 162, and/or multipliers 180. As used herein, the arithmetic columns 200 and 202 logically represent a column of multipliers with associated shift and add capabilities that may be formed from a physical implementation such as those discussed below with reference to FIGS. 7 and 8. The arithmetic columns 200 and 202 may support either two middle sized multipliers 160 (e.g., INT18 or INT16) or a large number of lower precision multipliers 180. Summation circuitry 162 is provided to combine different combinations of multipliers together into larger multipliers. Note that FIG. 6 is only a functional representation of the arithmetic circuitry that may be obtained in the DSP block 120C, and not a physical implementation. Indeed, the column block 202 of FIG. 6 is a smaller subset of the structures that will be discussed further below with reference to FIGS. 7, 8, 9 and 10.

FIG. 7 shows a physical implementation of the first column 200. A large number of relatively low precision multipliers 220 (e.g., INT8, INT9, INT10) are provided. Of these, there may be a lower-precision set 222 of one or more lower-precision multipliers 224 (e.g., INT8) and a higher-precision set 226 of higher-precision multipliers 228 (e.g., INT10). In other examples, the multipliers 220 may include many different sets of multipliers of different precisions or all of the multipliers 220 may have the same precision. In any case, the outputs of the multipliers 220 can be shifted relative to each other by an intermediate multiplexer network 230 and summed by following summation circuitry 232 or 234. For example, the intermediate multiplexer network 230 may receive outputs of the multipliers 220 and route the outputs to other multipliers 220 or into the summation circuitry 232 to effectively create the capabilities shown in FIGS. 5 and 6. In one example, the intermediate multiplexer network 230 may, in the case of providing higher-precision multiplication by effectively stitching together multiple multipliers 220, route the outputs of the multipliers 220 to the summation circuitry 232. In another example, in the case of providing AI tensor operations, the intermediate multiplexer network 230 may not be used, but rather the outputs of the multipliers 220 may be routed to the summation circuitry 234.

How the intermediate multiplexer network 230 routes the data through the DSP block 120C may be set by a fixed configuration defined in the configuration bitstream (e.g., the program 20 illustrated in FIG. 1) and programmed into configuration random access memory (CRAM) associated with the DSP block 120C, or may be defined dynamically (e.g., based on configuration data from a host computer interacting with the integrated circuit device 12 or from a system design programmed into the integrated circuit device 12). Likewise, whether the output of the multipliers 220 enter the intermediate multiplexer network 230 or flow directly to the summation circuitry 234 may be likewise set by a fixed configuration defined in the configuration bitstream (e.g., the program 20 illustrated in FIG. 1) and programmed into configuration random access memory (CRAM) associated with the DSP block 120C, or may be defined dynamically (e.g., based on configuration data from a host computer interacting with the integrated circuit device 12 or from a system design programmed into the integrated circuit device 12).

An input multiplexer network 236 may also be implemented in dedicated circuitry of the DSP block 120C (e.g., in a first column where the pre-adders 158 are located in FIG. 6) to apply different input patterns to different multipliers 220 to compose elements of larger multiplications. An input 238 to the multipliers 220 connected to the input multiplexer network 236 may have a greater width than that of the input 150 to account for possible inputs into the multipliers 220. For instance, if there is one INT8 multiplier 224 and nine INT10 multipliers 228, there may be 196 possible inputs. In this way, the input multiplexer network 236 and input 238 may act as the input 150 and 204 of the logical diagram of FIG. 6.

Depending on how the input multiplexer 236 and intermediate multiplexer 230 are configured, the following multipliers may be constructed from nine INT10 multipliers: two 18×18s, sum of two 18×18s, 27×27, 36×18. Smaller multipliers, for example INT9, may also be used, but here the larger multipliers would be limited to two 16×16 (or sum thereof), or 24×24. To simplify the multiplexer network 230 (and also the following summation circuitry 232 or 234), a subset of combinations (e.g., such as only sum of two INT16 multipliers) could be supported. The two sets of multipliers 222 and 226 may have different combinations of multipliers supported, for example to make one set physically smaller and lower power. The precision of the smaller, lower-precision multipliers 224 and the higher-precision multipliers 228 may not be the same. For example, an INT8 tensor could be implemented by using a number of INT9 or INT10 multipliers (in order to construct the larger multipliers), and one or more INT8 multipliers to make up the size of the tensor, for example, 10 or 12 elements.

When the DSP block 120C is operated in a tensor mode, the first column 200 and the second column 202 may both receive the same inputs (e.g., 108 bits from input 150) and perform multiplication based on data from the input 150 and data that has been pre-loaded in the banks of coefficient storage 182. When the DSP block 120C is operated in a complex mode, an input 240 (e.g., having a width of up to 64 bits) may go into a second input multiplexer network 242 (e.g., logically positioned in a first column where the pre-adders 158 are located in FIG. 6). The second input multiplexer network 242 may route data to an input 244 (e.g., having a possible width of 144 bits) for the second arithmetic column 202.

FIG. 8 illustrates a physical implementation of the second column 202. The second arithmetic column 202 may use a slightly different multiplexing/demultiplexing pattern carried out by the input multiplexer 242 or an intermediate multiplexer network 246. For example, when the DSP block 120C is used for complex arithmetic, the first column 200 may implement a real result of a complex multiplication and the second column 202 may implement an imaginary result of the complex multiplication. Thus, in such an example, the intermediate multiplexer network 246 may route data from just a subset of the multipliers 220 of the second column 202 to produce, for example, a 16×16 multiplier for a complex multiply. In other words, when the DSP block 120C operates in a complex mode, the intermediate multiplexer network 246 of the column 202 may have a different routing pattern than the intermediate multiplexer network 236 of the column 200.

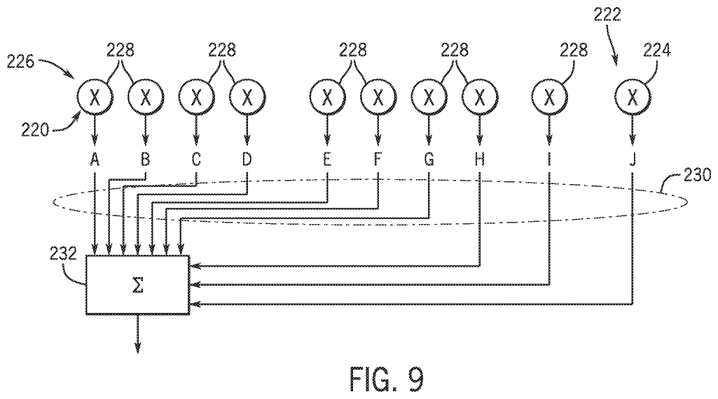

FIG. 9 shows how a tensor structure (e.g., a sum of ten multipliers in this case) may be implemented in the column 200 or 202. Here, ten multipliers 224 and 228 output results A, B, C, D, E, F, G, H, I, and J that are routed by the intermediate multiplexer network 230 and summed together in the summation circuitry 232. Additionally or alternatively, the ten multipliers 224 and 228 output results A, B, C, D, E, F, G, H, I, and J may be routed directly to summation circuitry 234 (e.g., as defined by a configuration in configuration memory (CRAM)). While ten multipliers 224 and 228 are shown here, a tensor structure may be implemented using any other suitable number of multipliers, which may have different precisions or a mix of different precisions. For example, the multiplier 224 that outputs result J may be an 8×8 multiplier (e.g., 16b output) and the remaining multipliers 228 may be 10×10 multipliers (e.g., for a possible 20b output), but only 16b of the larger multipliers 228 may be used for the tensor operation. The summation circuitry 232 may be implemented in many different ways, such as compression (e.g., Wallace tree, followed by a carry propagate adder), counters (e.g., where individual columns are converted to a weight using unary to binary conversion, then followed by some type of adder tree), a simple adder tree (e.g., including a network of carry propagate adders), or a combination of the above.

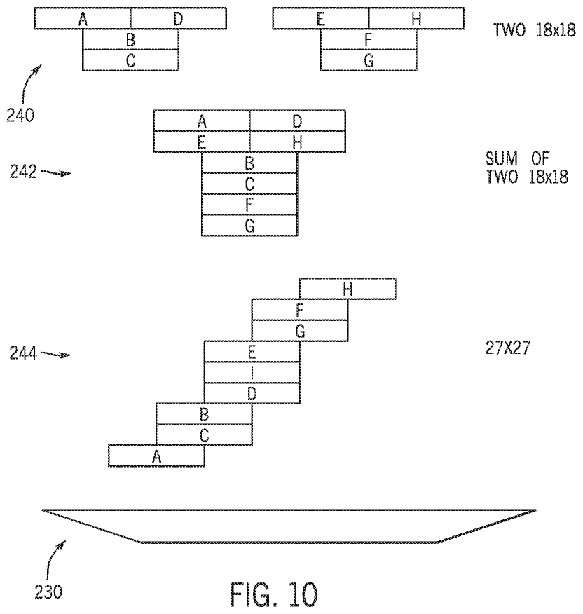

FIG. 10 shows multiplexer patterns that may be used for routing the outputs of the multipliers 220 shown in FIG. 7 to construct a variety of different larger multipliers. In the example of FIG. 10, the outputs of the higher-precision multipliers 228 among the multipliers 220 (e.g., outputs A, B, C, D, E, F, G, H, and/or I) are used to construct two independent 18×18 multipliers (pattern 240), a sum of two 18×18 multipliers (pattern 242), or a 27×27 multiplier (pattern 244). Each block (labeled with the 20b multiplier output) is shifted through the intermediate multiplexer network 230, and then summed. This all may take place in one cycle. As with the tensor example of FIG. 9, the summation of the different vectors can be accomplished by any suitable known method or combination of methods, such as compression (e.g., Wallace tree, followed by a carry propagate adder), counters (e.g., where individual columns are converted to a weight using unary to binary conversion, then followed by some type of adder tree), a simple adder tree (e.g., including a network of carry propagate adders), or a combination of the above

In the example of FIG. 10, 10×10 multipliers are used as the base to obtain the output values A, B, C, D, E, F, G, H, and/or I, as each output block shown in FIG. 10 contains an 18b value. This way, any multiplier 228 can be dynamically configured to be signed*signed, unsigned*unsigned, or signed*unsigned by either extending the MSB of a 9-bit input or zeroing the 10th bit. Additionally or alternatively, multipliers 220 that can be dynamically configured between signed and unsigned inputs could be used. Different base sizes (instead of 10b) can be used, but this would then result in different precision larger multipliers that could be supported unless the multipliers 220 are larger than 10×10.

In the multiplexer pattern 244 (27×27) case, the multiplier that supplied output A multiplies signed*signed data, and the multiplier that supplied output H multiplies unsigned*unsigned data. Several other multipliers may be unsigned*unsigned as well, with the remaining signed*unsigned (e.g., signed*unsigned B,C,D,E; unsigned*unsigned I,F,G,H; signed*signed A). In the 18×18 cases, A and E are signed*signed, D and H are unsigned*unsigned, and the remaining ones are signed*unsigned.

It may be seen that some of the mux patterns 240, 242, and 244 are subsets of each other. For example, the two independent 18×18 patterns 240, 242 also form part of the 27×27 pattern 244. This reduces gate complexity. Sign extensions for the various vectors are not shown in the mux patterns, but may be used.

In some cases, the tensor may be built as shown in FIG. 9, but the larger multipliers with outputs A to I may be 9×9 multipliers instead of 10×10 multipliers. Applied to the example of FIG. 10, only one of the patterns 240, 242, or 244 may be used at a particular time, which is the sum of two multipliers. But as the multipliers with outputs A to I in that column are 9×9, only a sum of two 16×16 multipliers may be constructed. These may be combined with two 18×18 multipliers in the other column (acting down as 16×16 multipliers) to build a complex 16b multiplier. As there are only 64 unique inputs for a 16b complex multiplier, this will be a relatively low utilization of the total available input (the same as two independent 16b multipliers) and thus the DSP block 120C will be able to use the DSP block 120A or 120B I/O without modification. Additional multiplexing may be performed at the input stage to distribute the 64 inputs to the correct multipliers.

The DSP block 120C may operate in a complex mode. For example, a subset of the data from the input 150 may enter the input multiplexer network 236 to be distributed to the multipliers 220 of the first column 200 for a real portion of the complex multiplication. Another subset of the data from the input 150 may enter the input multiplexer network 242 to be distributed to the multipliers 220 of the first column 202 for an imaginary portion of the complex multiplication.

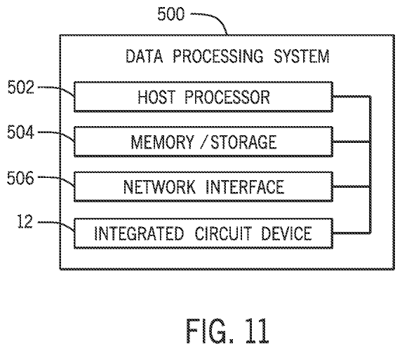

The integrated circuit device 12 may be a component included in a data processing system, such as a data processing system 500, shown in FIG. 11. The data processing system 500 may include the integrated circuit system 12 (e.g., a programmable logic device), a host processor 502, memory and/or storage circuitry 504, and a network interface 506. The data processing system 500 may include more or fewer components (e.g., electronic display, user interface structures, application specific integrated circuits (ASICs)). The integrated circuit device 12 may be used to efficiently implement a symmetric FIR filter or perform complex multiplication. The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams, mapping function) for programming the integrated circuit device 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### Example Embodiments

EXAMPLE EMBODIMENT 1. An integrated circuit device comprising:
programmable logic circuitry; and
an arithmetic block comprising:
   a plurality of hardened multipliers;
   hardened summation circuitry; and
   an intermediate multiplexer network configurable to route data multiplied by at least some of the plurality of hardened multipliers between the plurality of hardened multipliers and the hardened summation circuitry to perform either a first number of lower-precision multiplication operations or a second number, lower than the first number, of higher-precision multiplication operations.

EXAMPLE EMBODIMENT 2. The integrated circuit device of example embodiment 1, wherein the arithmetic block is configurable to operate in a higher-precision mode and a lower-precision tensor mode.

EXAMPLE EMBODIMENT 3. The integrated circuit device of example embodiment 1, wherein the arithmetic block comprises multiple arithmetic columns respectively configurable to multiply a first dimension of inputs common to the multiple arithmetic columns with a second dimension of inputs specific to the respective multiple arithmetic columns.

EXAMPLE EMBODIMENT 4. The integrated circuit device of example embodiment 3, wherein the arithmetic block comprises a plurality of banks of coefficient storage configurable to store the second dimension of inputs specific to the respective multiple arithmetic columns.

EXAMPLE EMBODIMENT 5. The integrated circuit device of example embodiment 1, wherein the arithmetic block comprises multiple arithmetic columns comprising a respective set of the hardened multipliers and the hardened summation circuitry, wherein the multiple arithmetic columns are configurable to have identical arithmetic functionality.

EXAMPLE EMBODIMENT 6. The integrated circuit device of example embodiment 5, wherein the multiple arithmetic columns have different respective arrangements of arithmetic components.

EXAMPLE EMBODIMENT 7. The integrated circuit device of example embodiment 5, wherein the multiple arithmetic columns are configurable to have different arithmetic functionality.

EXAMPLE EMBODIMENT 8. The integrated circuit device of example embodiment 1, wherein the arithmetic block comprises multiple arithmetic columns comprising a respective set of the hardened multipliers and the hardened summation circuitry, wherein a first of the multiple arithmetic columns is configurable to implement a real result of a complex multiplication and a second of the multiple arithmetic columns is configurable to implement a complex result of the complex multiplication.

EXAMPLE EMBODIMENT 9. The integrated circuit device of example embodiment 7, wherein the at least one multiplier of the second precision is greater in number than the at least one multiplier of the first precision.

EXAMPLE EMBODIMENT 10. The integrated circuit device of example embodiment 9, wherein the plurality of hardened multipliers comprises one multiplier of INT8 precision and at least eight multipliers of INT9 or INT10 precision.

EXAMPLE EMBODIMENT 11. The integrated circuit device of example embodiment 10, wherein the plurality of hardened multipliers comprises no more than one multiplier of INT8 precision and comprises nine multipliers of INT9 or INT10 precision. EXAMPLE EMBODIMENT 12. The integrated circuit device of example embodiment 1, wherein the intermediate multiplexer network is configurable to operate in one of a plurality of configurations comprising:
a first configuration that routes the data between the plurality of hardened multipliers and the arithmetic block to perform the first number of lower-precision multiplication operations;
a second configuration that routes the data between the plurality of hardened multipliers and the arithmetic block to perform the second number of higher-precision multiplication operations, wherein the second number of higher-precision multiplication operations comprises one 27×27 multiplication;
a third configuration that routes the data between the plurality of hardened multipliers and the arithmetic block to perform the second number of higher-precision multiplication operations, wherein the second number of higher-precision multiplication operations comprises one 18×18 multiplication; and
a fourth configuration that routes the data between the plurality of hardened multipliers and the arithmetic block to perform the second number of higher-precision multiplication operations, wherein the second number of higher-precision multiplication operations comprises two 18×18 multiplications.

EXAMPLE EMBODIMENT 13. The integrated circuit device of example embodiment 1, wherein the arithmetic logic block comprises an input multiplexer network configurable to route inputs to different multipliers of the plurality of multipliers.

EXAMPLE EMBODIMENT 14. One or more tangible, non-transitory, machine-readable media comprising instructions that, when executed by data processing circuitry, perform the following operations:
configuring a multiplexer network of a first hardened arithmetic block circuitry of an integrated circuit device with one of a plurality of configurations, wherein:
   a first configuration of the plurality of configurations causes the first hardened arithmetic block circuitry to perform at least eight multiplication operations of a first precision; and
   a second configuration of the plurality of configurations causes the first hardened arithmetic block circuitry to perform at least one multiplication operation of a second precision higher than the first precision.

EXAMPLE EMBODIMENT 15. The one or more tangible, non-transitory, machine-readable media of example embodiment 14, wherein the first precision comprises no greater than 10b and the second precision is at least 18b.

EXAMPLE EMBODIMENT 16. The one or more tangible, non-transitory, machine-readable media of example embodiment 15, wherein the second precision is at least 27b.

EXAMPLE EMBODIMENT 17. The one or more tangible, non-transitory, machine-readable media of example embodiment 14, wherein a third configuration of the plurality of configurations causes the first hardened arithmetic block circuitry to perform at least one multiplication operation of a third precision higher than the second precision.

EXAMPLE EMBODIMENT 18. Flexible digital signal processing circuitry comprising:
a plurality of hardened multipliers;
hardened summation circuitry; and
an intermediate multiplexer network configurable to, in a first configuration, route data between the plurality of hardened multipliers and the hardened summation circuitry to perform a plurality of lower-precision multiplication operations and, in a second configuration, route the data between the plurality of hardened multipliers and the hardened summation circuitry to perform at least one higher-precision multiplication operation.

EXAMPLE EMBODIMENT 19. The digital signal processing circuitry of example embodiment 18, wherein the intermediate multiplexer network is configurable to, in the first configuration, route the data between the plurality of hardened multipliers and the hardened summation circuitry to perform a tensor operation involving at least eight multiplication operations of INT10 precision or lower.

EXAMPLE EMBODIMENT 20. The digital signal processing circuitry of example embodiment 18, wherein the intermediate multiplexer network is configurable to, in the second configuration, route the data between the plurality of hardened multipliers and the hardened summation circuitry to perform at least one multiplication operation of INT18 precision or higher.

What is claimed is:

1. An integrated circuit device comprising:
programmable logic circuitry; and
an arithmetic block comprising:
a plurality of hardened multipliers;
hardened summation circuitry; and
an intermediate multiplexer network configurable to route data multiplied by at least some of the plurality of hardened multipliers between the plurality of hardened multipliers and the hardened summation circuitry to perform either a first number of lower-precision multiplication operations or a second number, lower than the first number, of higher-precision multiplication operations.

2. The integrated circuit device of claim 1, wherein the arithmetic block is configurable to operate in a higher-precision digital signal processing mode and a lower-precision tensor mode.

3. The integrated circuit device of claim 1, wherein the arithmetic block comprises multiple arithmetic columns respectively configurable to multiply a first dimension of inputs common to the multiple arithmetic columns with a second dimension of inputs specific to the respective multiple arithmetic columns.

4. The integrated circuit device of claim 3, wherein the arithmetic block comprises a plurality of banks of coefficient storage configurable to store the second dimension of inputs specific to the respective multiple arithmetic columns.

5. The integrated circuit device of claim 1, wherein the arithmetic block comprises multiple arithmetic columns comprising a respective set of the hardened multipliers and the hardened summation circuitry, wherein the multiple arithmetic columns are configurable to have identical arithmetic functionality.

6. The integrated circuit device of claim 5, wherein the multiple arithmetic columns have different respective arrangements of arithmetic components.

7. The integrated circuit device of claim 5, wherein the multiple arithmetic columns are configurable to have different arithmetic functionality.

8. The integrated circuit device of claim 1, wherein the arithmetic block comprises multiple arithmetic columns comprising a respective set of the hardened multipliers and the hardened summation circuitry, wherein a first of the multiple arithmetic columns is configurable to implement a real result of a complex multiplication and a second of the multiple arithmetic columns is configurable to implement a complex result of the complex multiplication.

9. The integrated circuit device of claim 7, wherein the at least one multiplier of the second precision is greater in number than the at least one multiplier of the first precision.

10. The integrated circuit device of claim 9, wherein the plurality of hardened multipliers comprises one multiplier of INT8 precision and at least eight multipliers of INT9 or INT10 precision.

11. The integrated circuit device of claim 10, wherein the plurality of hardened multipliers comprises no more than one multiplier of INT8 precision and comprises nine multipliers of INT9 or INT10 precision.

12. The integrated circuit device of claim 1, wherein the intermediate multiplexer network is configurable to operate in one of a plurality of configurations comprising:
a first configuration that routes the data between the plurality of hardened multipliers and the arithmetic block to perform the first number of lower-precision multiplication operations;
a second configuration that routes the data between the plurality of hardened multipliers and the arithmetic block to perform the second number of higher-precision multiplication operations, wherein the second number of higher-precision multiplication operations comprises one 27×27 multiplication;
a third configuration that routes the data between the plurality of hardened multipliers and the arithmetic block to perform the second number of higher-precision multiplication operations, wherein the second number of higher-precision multiplication operations comprises one 18×18 multiplication; and
a fourth configuration that routes the data between the plurality of hardened multipliers and the arithmetic block to perform the second number of higher-precision multiplication operations, wherein the second number of higher-precision multiplication operations comprises two 18×18 multiplications.

13. The integrated circuit device of claim 1, wherein the arithmetic logic block comprises an input multiplexer network configurable to route inputs to different multipliers of the plurality of multipliers.

14. One or more tangible, non-transitory, machine-readable media comprising instructions that, when executed by data processing circuitry, perform the following operations:
configuring a multiplexer network of a first hardened arithmetic block circuitry of an integrated circuit device with one of a plurality of configurations, wherein:
a first configuration of the plurality of configurations causes the first hardened arithmetic block circuitry to perform at least eight multiplication operations of a first precision; and
a second configuration of the plurality of configurations causes the first hardened arithmetic block circuitry to perform at least one multiplication operation of a second precision higher than the first precision.

15. The one or more tangible, non-transitory, machine-readable media of claim 14, wherein the first precision comprises no greater than 10b and the second precision is at least 18b.

16. The one or more tangible, non-transitory, machine-readable media of claim 15, wherein the second precision is at least 27b.

17. The one or more tangible, non-transitory, machine-readable media of claim 14, wherein a third configuration of the plurality of configurations causes the first hardened arithmetic block circuitry to perform at least one multiplication operation of a third precision higher than the second precision.

18. Flexible digital signal processing circuitry comprising:
a plurality of hardened multipliers;
hardened summation circuitry; and
an intermediate multiplexer network configurable to, in a first configuration, route data between the plurality of hardened multipliers and the hardened summation circuitry to perform a plurality of lower-precision multiplication operations and, in a second configuration, route the data between the plurality of hardened multipliers and the hardened summation circuitry to perform at least one higher-precision multiplication operation.

19. The digital signal processing circuitry of claim 18, wherein the intermediate multiplexer network is configurable to, in the first configuration, route the data between the plurality of hardened multipliers and the hardened summation circuitry to perform a tensor operation involving at least eight multiplication operations of INT10 precision or lower.

20. The digital signal processing circuitry of claim 18, wherein the intermediate multiplexer network is configurable to, in the second configuration, route the data between the plurality of hardened multipliers and the hardened summation circuitry to perform at least one multiplication operation of INT18 precision or higher.
